(19) United States
(12) Patent Application Publication
(10) Pub. No.: US 2012/0037214 A1
(43) Pub. Date: Feb. 16, 2012

(54) SOLAR CELL MODULE, SOLAR CELL ATTACHMENT STAND, PHOTOVOLTAIC POWER GENERATING SYSTEM

(76) Inventor: Kenichi Sagayama, Osaka (JP)

(21) Appl. No.: 13/263,415

(22) PCT Filed: Apr. 7, 2010
(86) PCT No.: PCT/JP2010/056318

§ 371 Date: Oct. 7, 2011

(51) Int. Cl. H01L 31/048; H01L 23/12

(52) U.S. Cl. 136/251; 248/121; 211/41.1

(57) ABSTRACT

To protect a solar cell panel and facilitate the attachment of the solar cell panel on a roof and the like. A solar cell module 2 includes a solar cell panel 20 and two reinforcing bars 21 that laterally cross the solar cell panel 20 and that are disposed and adhered on the rear surface of the solar cell panel 20. Each of the reinforcing bars 21 is in the form of a rectangular and flat plate having a length that is approximately the same as the lateral width of the solar cell panel 20. Both end portions of each reinforcing bar 21 are bent upwardly to form hooking portions 21a of each reinforcing bar 21. U-shaped notches are formed adjacent to both ends of each reinforcing bar 21, and the U-shaped parts are bent downwardly to form protruding engagement portions 21b. An example of the reinforcing bar 21 is made of a steel plate that is cut, bent, and subjected to plating.

### TECHNICAL FIELD

The present invention relates to a solar cell module, a solar cell attachment stand, and a photovoltaic power generating system.

### DESCRIPTION OF THE BACKGROUND ART

In conventional systems of this kind, a solar cell module in which four sides of a solar cell panel are held with a frame member has been used. This is because the solar cell panel is mainly made of a substrate made of glass and the like, and thus the solar cell panel itself is brittle. In order to make up for this disadvantage, it is effective to protect the four sides of the solar cell panel with the frame member.

Also, since it is difficult to directly install the solar cell panel having such brittleness on a roof and the like, it is preferable that the solar cell panel be held with the frame member, and the frame member be installed and secured on the roof and the like.

For example, patent document 1 discloses a system in which the four sides of a solar cell panel are held with a frame member, and the four corners of the frame member are provided with leg portions wherein two front leg portions are shorter than two rear leg portions to support the solar cell panel in a slanted manner.

### RELATED ART DOCUMENTS

### Patent Documents

Patent document 1: JP1999-177115A

### SUMMARY OF INVENTION

### Problems to be Solved by the Invention

Unfortunately, the frame member holding the four sides of the solar cell panel is a rectangular frame, has a large piece-part count, and is complicated in shape, which makes difficult the attachment work with respect to the four sides of the solar cell panel. This has served as one of the causes of difficulty in a reduction in cost of the solar cell panel.

The present invention has been made to solve the above problems, it is an object of the present invention to provide a solar cell module, a solar cell attachment stand, and a photovoltaic power generating system that protect a solar cell panel and facilitate the attachment of the solar cell panel on a roof and the like, even without use of a frame member to hold the four sides of the solar cell panel.

### Means of Solving the Problems

According to one aspect of the present invention, a solar cell module includes a solar cell panel and a reinforcing member. The reinforcing member is adhered to a rear surface of the solar cell panel and secured across opposing two sides of the solar cell panel. The reinforcing member includes an engagement portion protruding from a rear surface side of the reinforcing member.

Thus, a reinforcing member that is secured across opposing two sides of the solar cell panel is adhered and secured on the rear surface of the solar cell panel. This greatly improves the strength of the solar cell panel compared with the strength of the solar cell panel as a single entity.

An engagement portion protruding from the rear surface side of the reinforcing member is provided. The engagement portion is engaged with a stand or the like, thus installing the solar cell module.

Further, the solar cell module has a simple structure, with the reinforcing member merely adhered to the rear surface of the solar cell panel. This reduces the piece-part count and facilitates the attempt to reduce weight and cost of the solar cell module.

In the solar cell module according to the one aspect of the present invention, the reinforcing member may further include hooking portions bent at both ends of the reinforcing member. The reinforcing member may be secured on the rear surface of the solar cell panel with the opposing two sides of the solar cell panel held between the hooking portions at both ends of the reinforcing member.

The hooking portions of reinforcing bars protrude beyond the opposing two sides of the solar cell panel. Hence, when the solar cell module is placed on the ground or placed upright on a platform, the hooking portions directly contact the ground or the platform, which makes the sides of the solar cell panel detached and slightly afloat off the ground or the platform. This prevents chipping and damage to the sides of the solar cell panel.

In the solar cell module according to the one aspect of the present invention, the hooking portions at both ends of the reinforcing member each may have a height that is lower than a thickness of the solar cell panel.

This ensures that the hooking portions prevented from being a hindrance even when the solar cell panel is pressed at the portion of the reinforcing member.

The solar cell module according to the one aspect of the present invention may further include a shock absorbing member interposed between portions at both ends of the reinforcing member and the opposing two sides of the solar cell panel.

The shock absorbing member alleviates a shock, if any, on the end portions of the reinforcing member, thus preventing damage to the solar cell panel.

In the solar cell module according to the one aspect of the present invention, the solar cell panel may include a thin-film semiconductor layer on a substrate. The thin-film semiconductor may be configured to carry out photoelectric conversion.

As the substrate, a glass plate is oftentimes employed in many cases. Since the strength of the substrate is low, applying the prevent invention is effective.

In the solar cell module according to the one aspect of the present invention, the reinforcing member may include side portions bent at the both sides of the reinforcing member.

Thus, side portions bent at the both sides of the reinforcing member are formed. This improves the bending strength of the reinforcing member and the strength of the solar cell module.

According to another aspect of present invention, a solar cell attachment stand to support a solar cell panel includes a reinforcing member, at least one placing member, and fastening means. The reinforcing member is superimposed on a rear surface of the solar cell panel and secured across opposing two sides of the solar cell panel. On the at least one placing member, the reinforcing member on the rear surface of the solar cell panel is placed and secured. The fastening means is for fastening the placing member to the reinforcing member on the rear surface of the solar cell panel. The placing member and the reinforcing member on the rear surface of the solar cell panel include engagement portions engaged with one another.

Thus, the reinforcing member on the rear surface of the solar cell panel is placed on the placing member, and the reinforcing member on the rear surface of the solar cell panel and the placing member are fastened to one another. This secures the solar cell panel. Additionally, the reinforcing member on the rear surface of the solar cell panel and the placing member include engagement portions engaged with one another. This facilitates the positioning of the solar cell panel on the placing member.

In the solar cell attachment stand according to the other aspect of the present invention, the reinforcing member may further include hooking portions bent at both ends of the reinforcing member. The reinforcing member may be secured on the rear surface of the solar cell panel with the opposing two sides of the solar cell panel held between the hooking portions at both ends of the reinforcing member.

In the solar cell attachment stand according to the other aspect of the present invention, the hooking portions at both ends of the reinforcing member each may have a height that is lower than a thickness of the solar cell panel.

In the solar cell attachment stand according to the other aspect of the present invention, a solar cell module including the reinforcing member integrally adhered to the rear surface of the solar cell panel may be used.

The solar cell attachment stand according to the other aspect of the present invention may further include a shock absorbing member interposed between portions at both ends of the reinforcing member and the opposing two sides of the solar cell panel.

The solar cell attachment stand according to the other aspect of the present invention may further include a plurality of crosspieces disposed in parallel to each other with a distance provided therebetween. The distance may be at least same as a separation distance between the opposing two sides of the solar cell panel. The at least one placing member may include a plurality of placing members movably supported on the respective crosspieces in a solar cell panel aligning direction. A plurality of solar cell panels may be disposed between the crosspieces. The placing members may be movable to adjust positions of the placing members to positions of reinforcing members of adjacent solar cell panels among the plurality of solar cell panels. The engagement portion of each of the placing members and the engagement portion of each of the reinforcing members on the rear surface of the solar cell panel may be engaged with one another by fastening of the fastening means.

The movability of the placing members provides a tolerance to the positioning of the solar cell module, which facilitates the installment of the solar cell module.

In the solar cell attachment stand according to the other aspect of the present invention, the reinforcing member may include side portions bent at the both sides of the reinforcing member.

Thus, side portions bent at the both sides of the reinforcing member are formed. This improves the bending strength of the reinforcing member, the strength of the solar cell module, and further the strength of the solar cell attachment stand.

According to still another aspect of the present invention, a photovoltaic power generating system includes the solar cell attachment stand according to the other aspect of the present invention.

This photovoltaic power generating system facilitates the installation work of a large number of solar cell panels and ensures a drastic cost reduction.

### Effects of the Invention

In the aspects of the present invention, a reinforcing member secured across opposing two sides of the solar cell panel is adhered and secured on the rear surface of the solar cell panel. This improves the strength of the solar cell panel compared with the strength of the solar cell panel as a single entity.

Additionally, an engagement portion protruding from the rear surface side of the reinforcing member is provided. The engagement portion is engaged with a stand or the like, thus installing the solar cell module. This facilitates the installation work of a large number of solar cell panels and ensures a drastic cost reduction.

Further, the solar cell module has a simple structure, with the reinforcing member merely adhered to the rear surface of the solar cell panel. This reduces the piece-part count and facilitates the attempt to reduce weight and cost of the solar cell module.

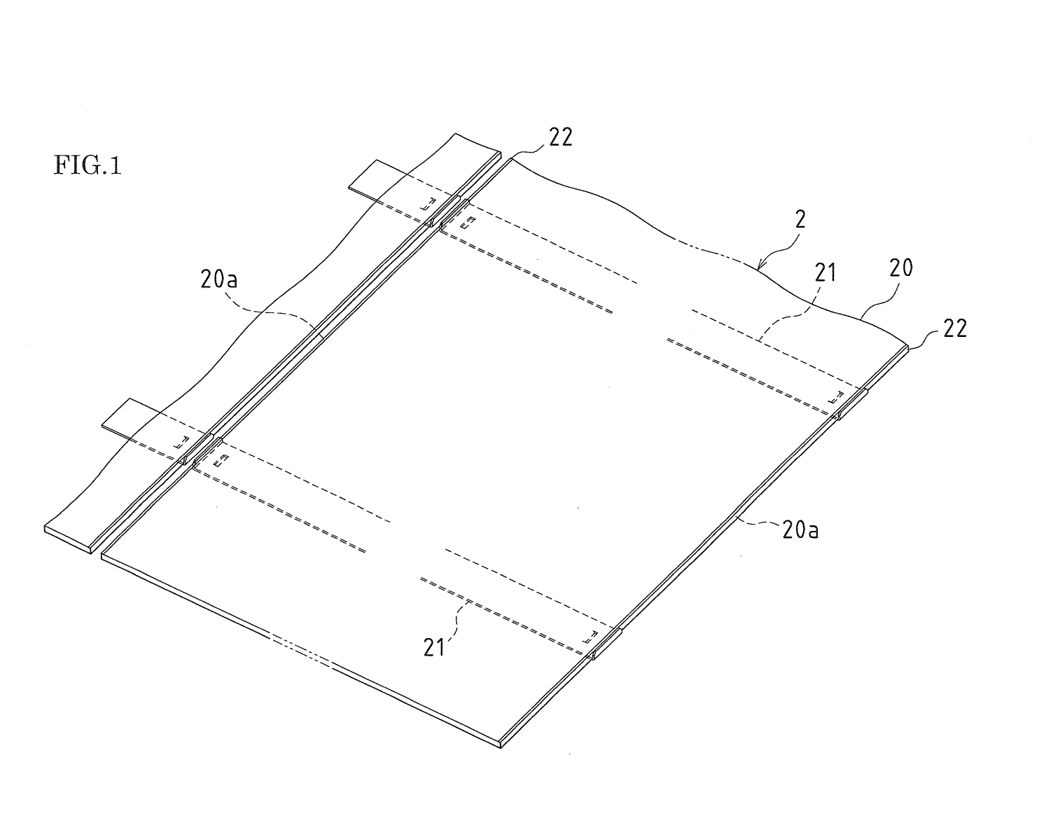

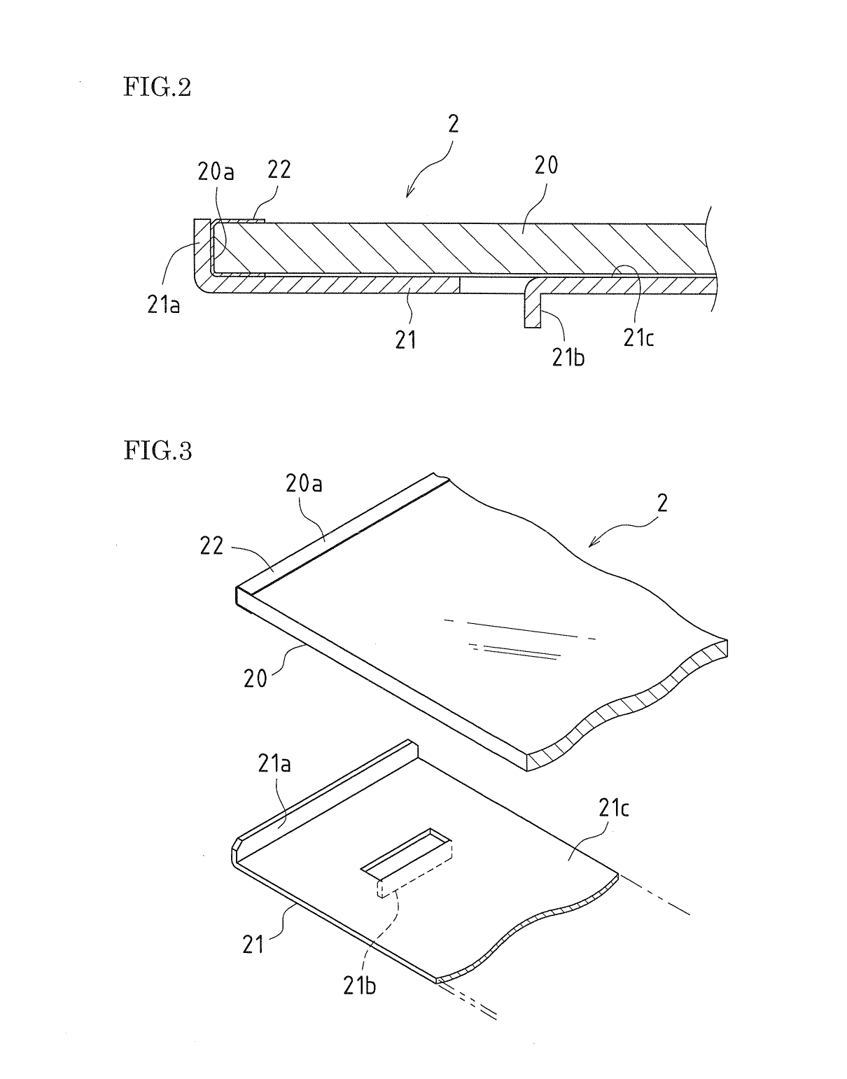

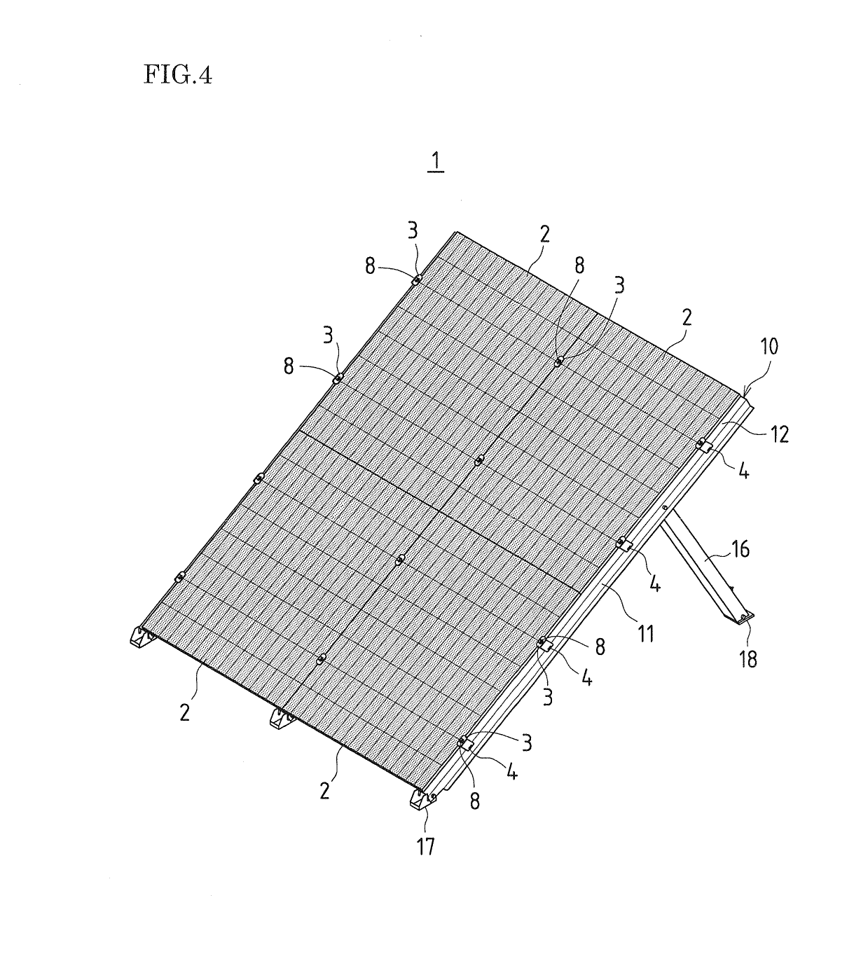

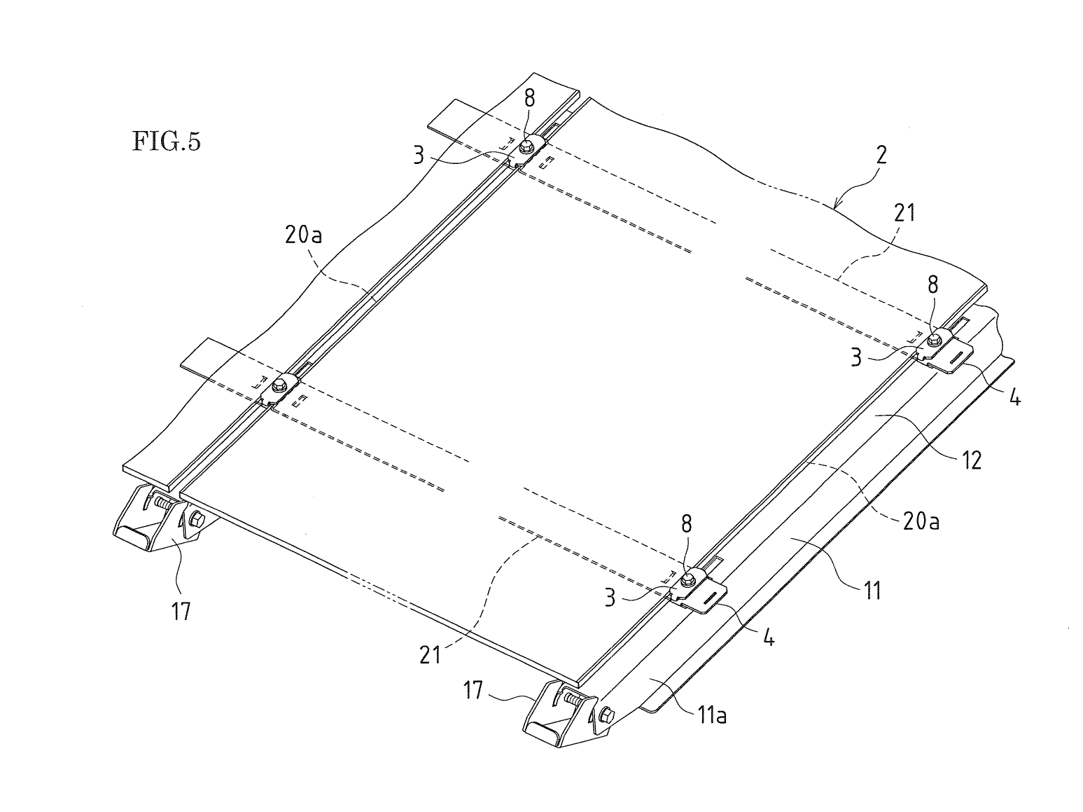

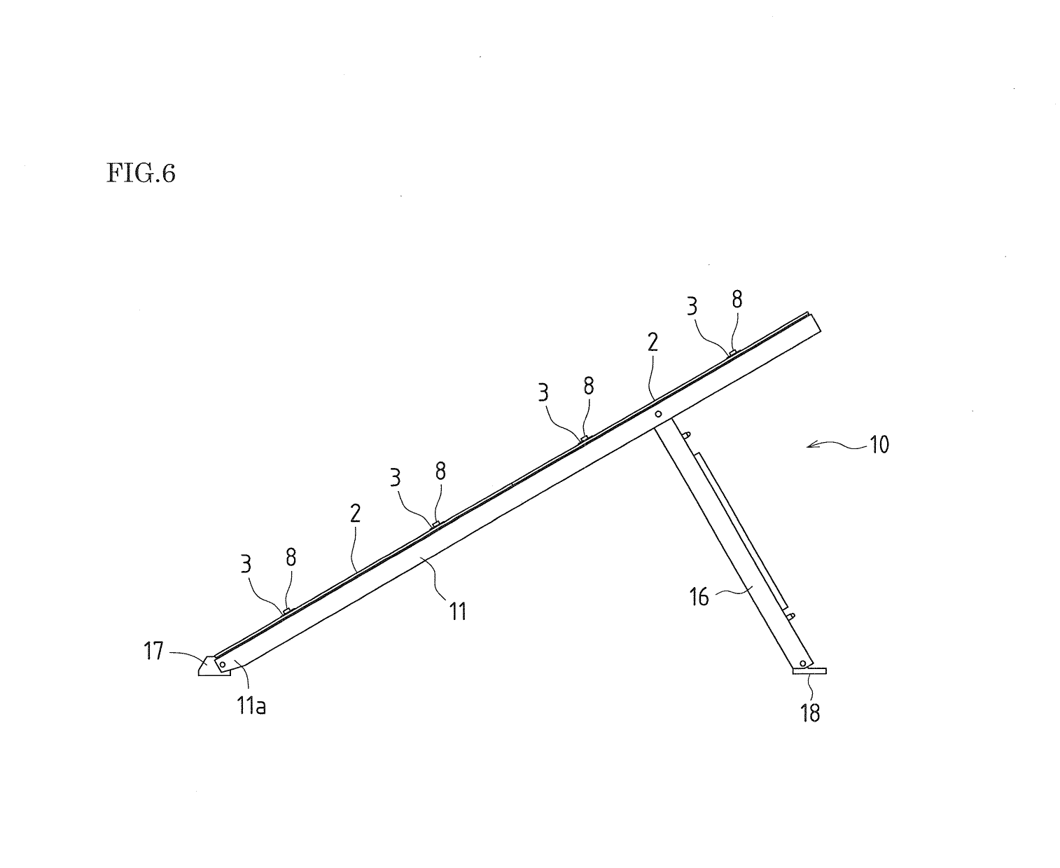

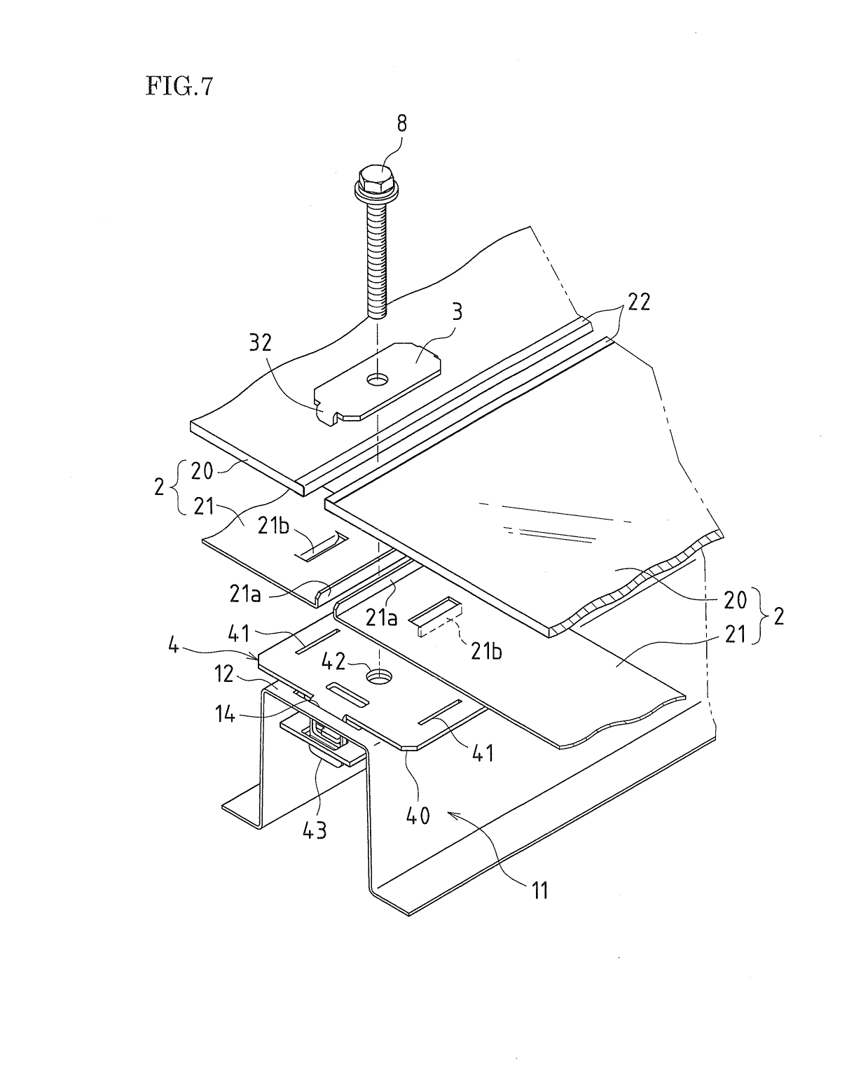

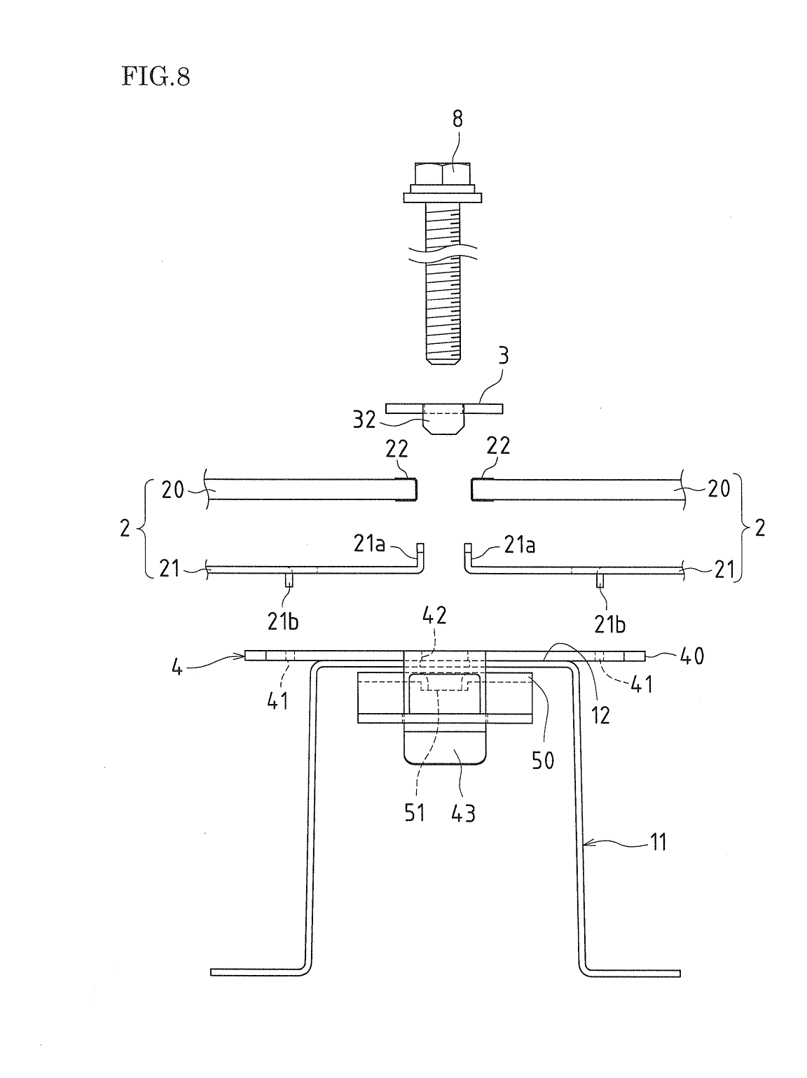

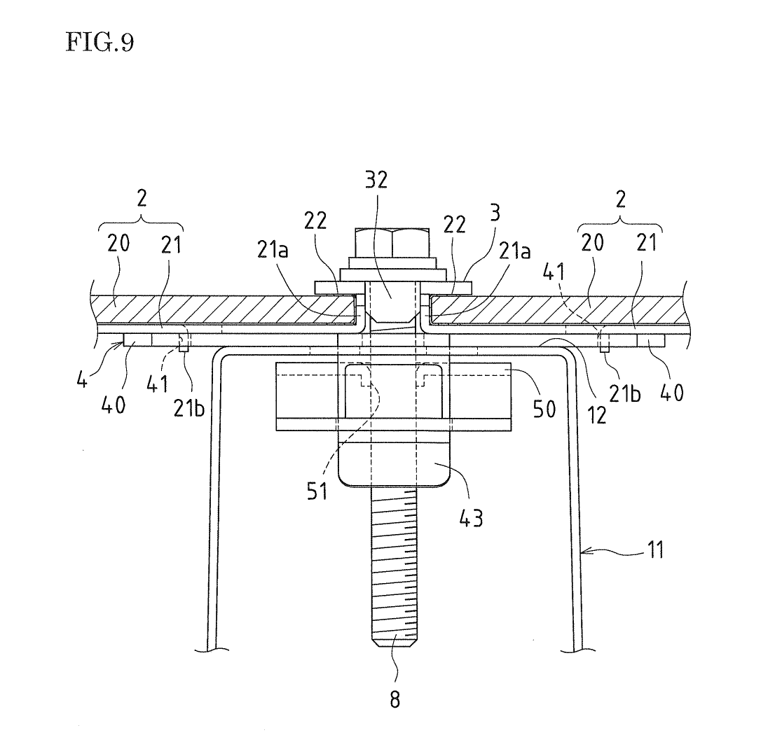

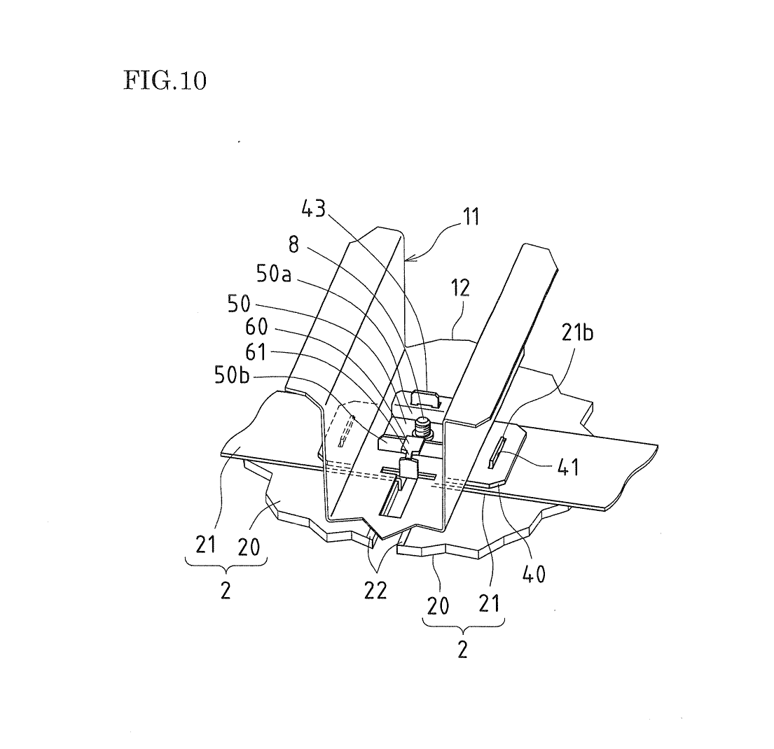

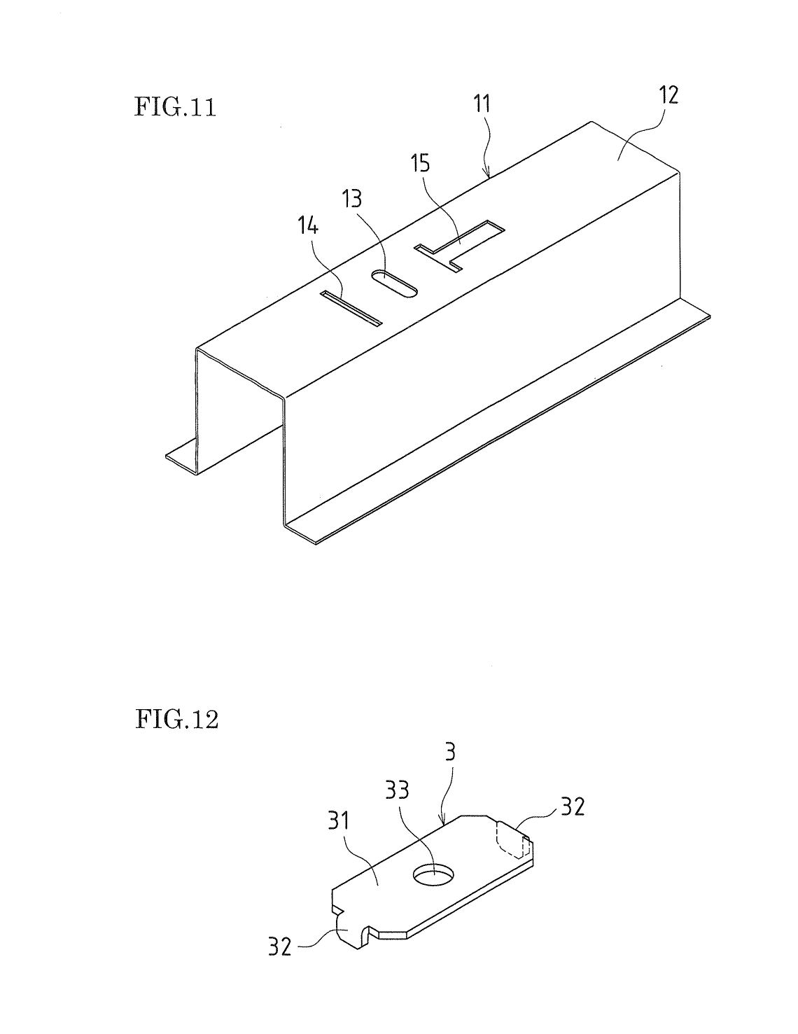

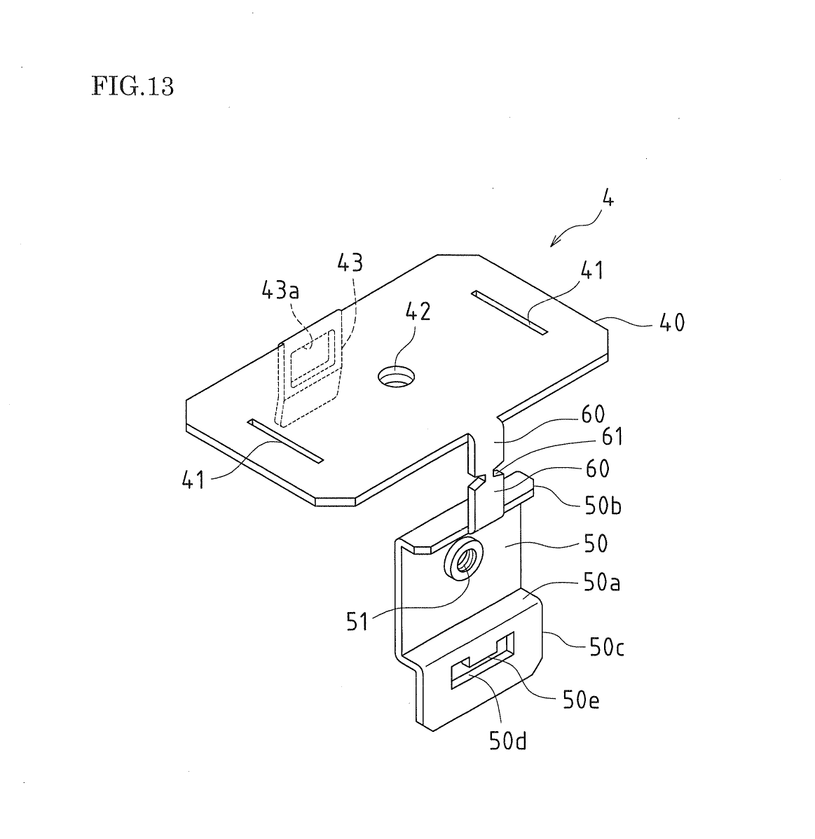

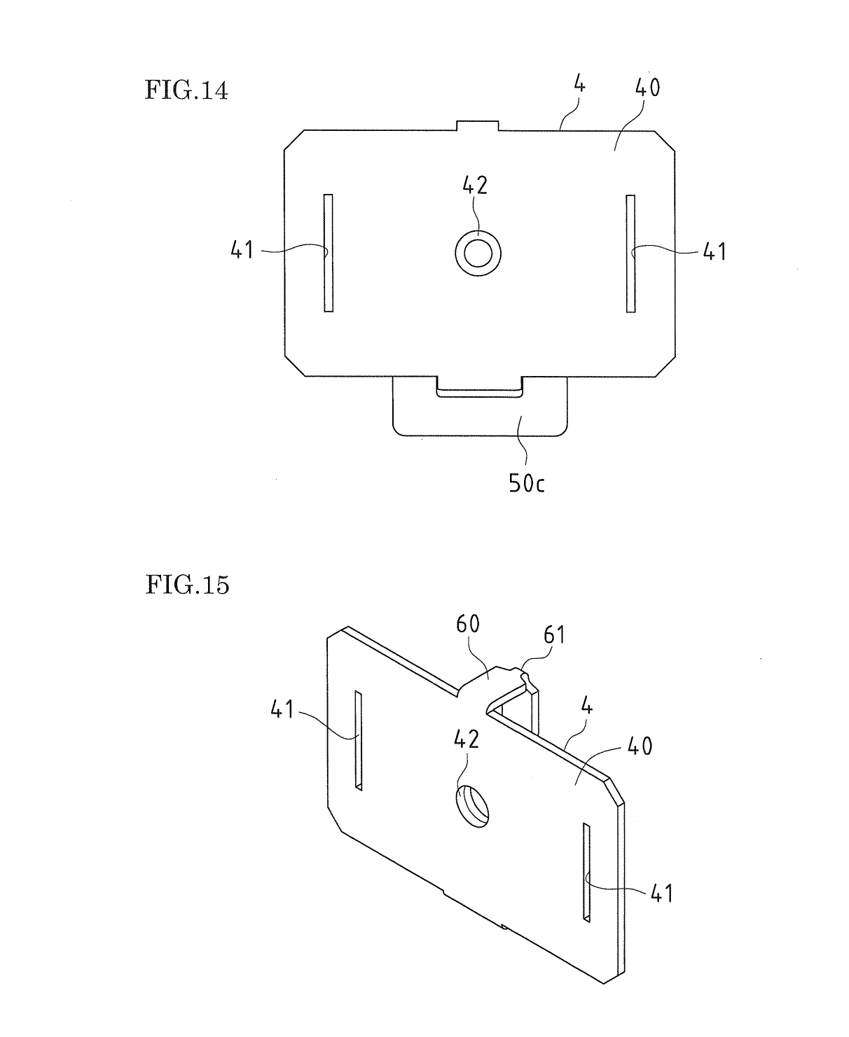

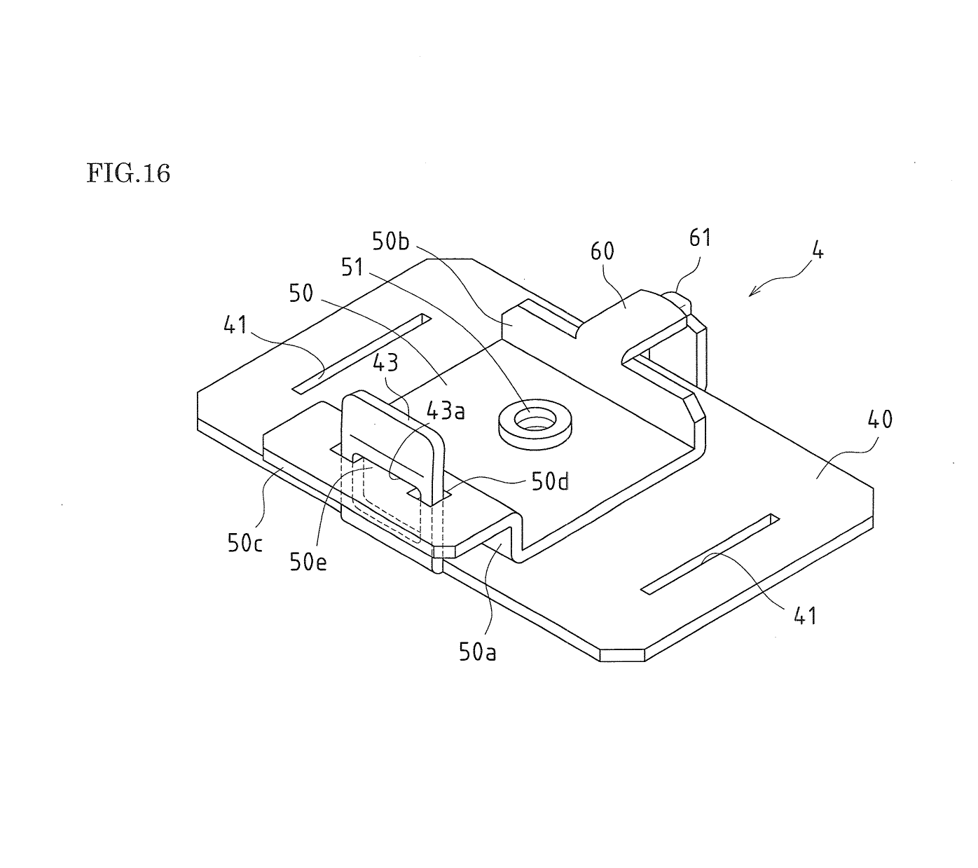

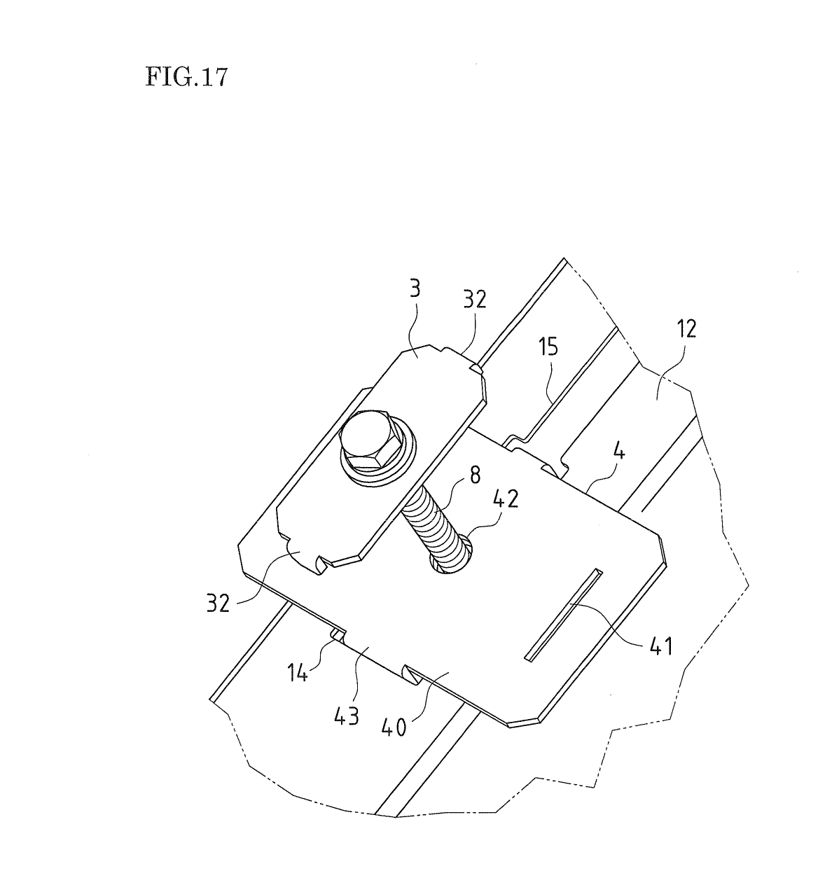

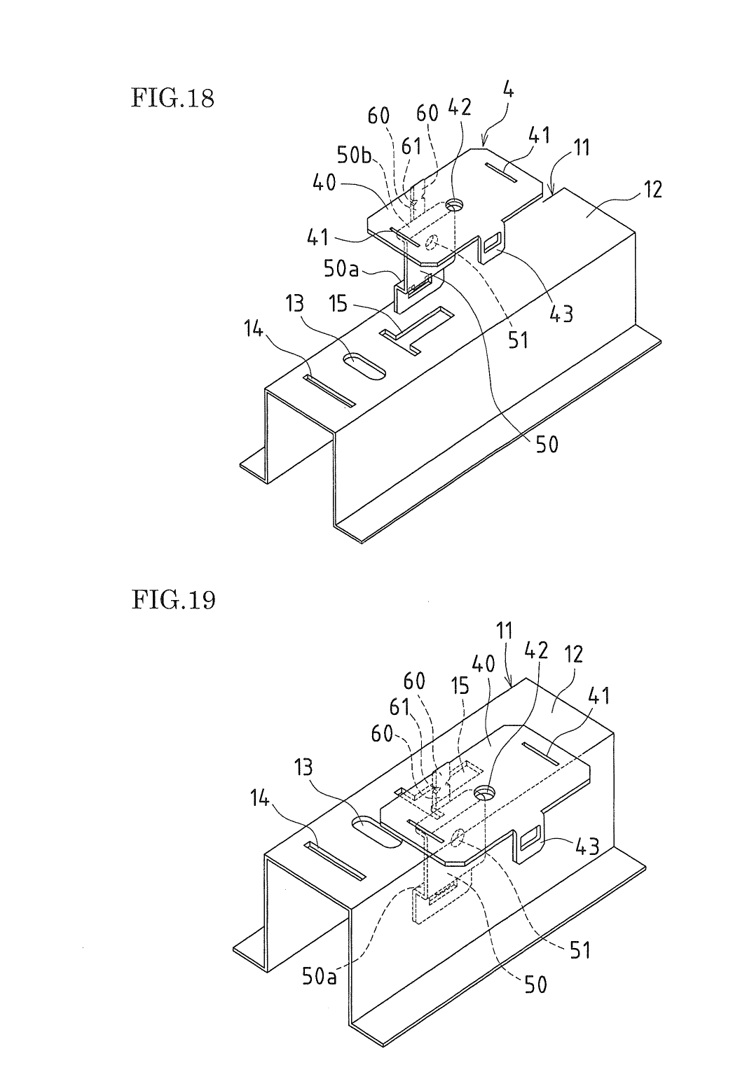

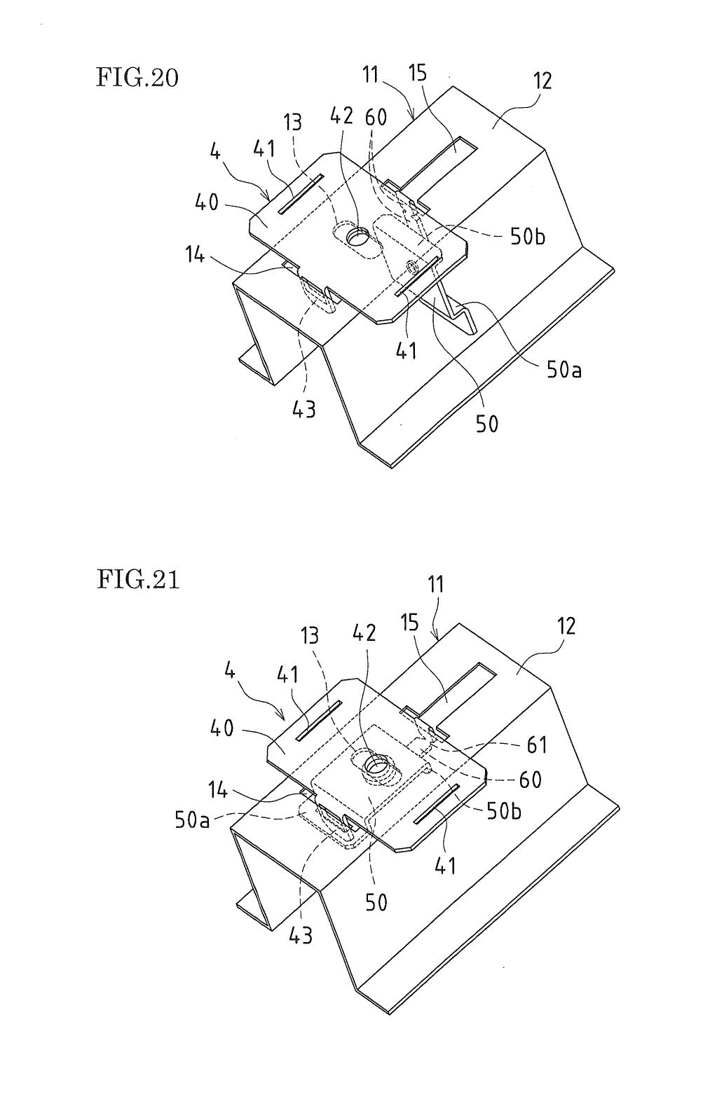

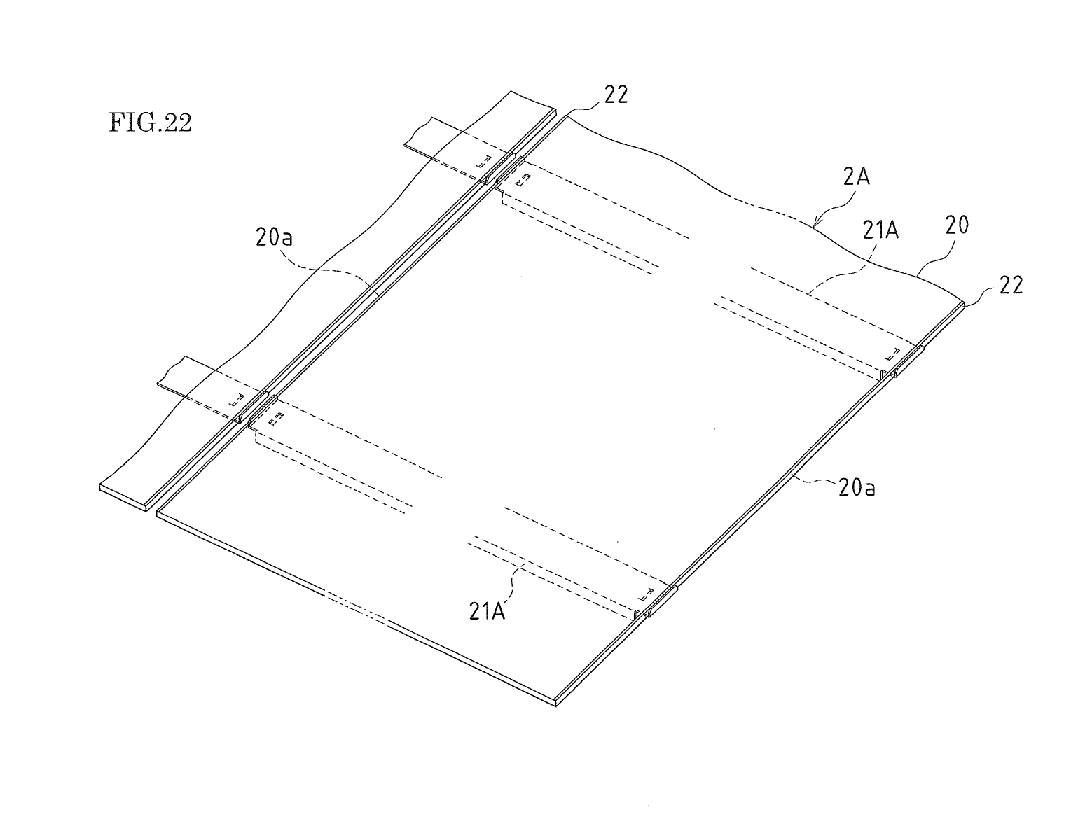

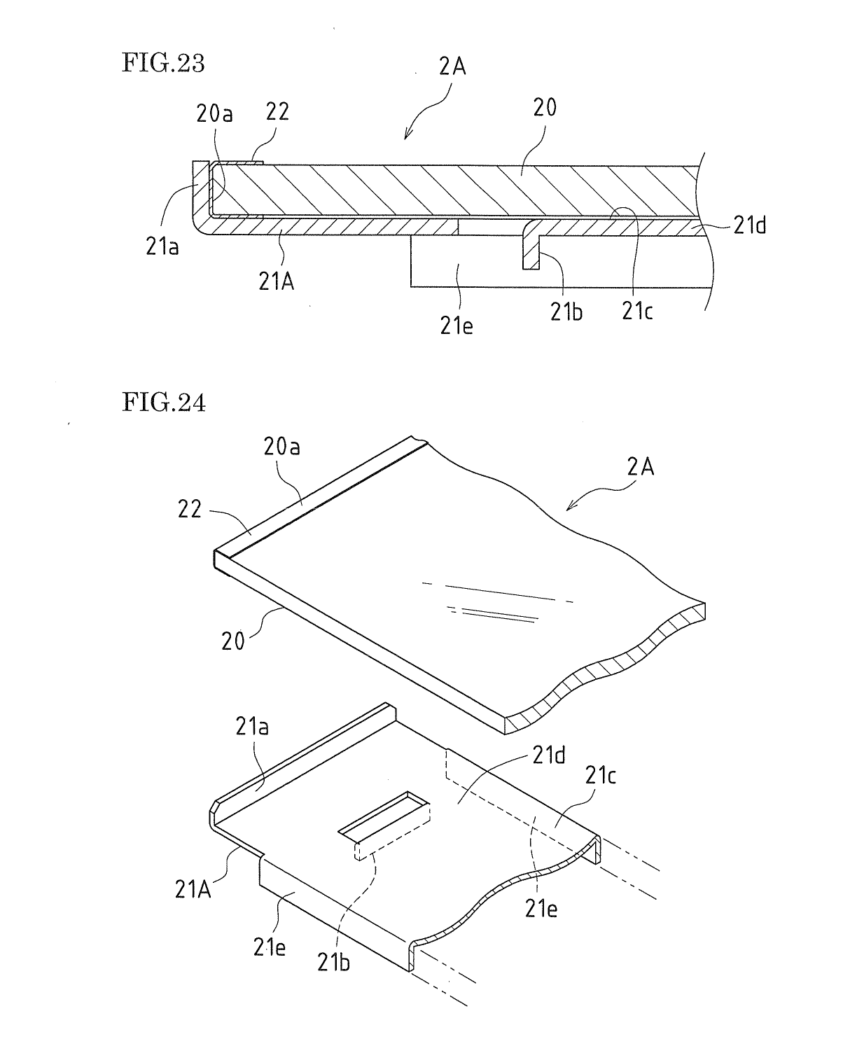

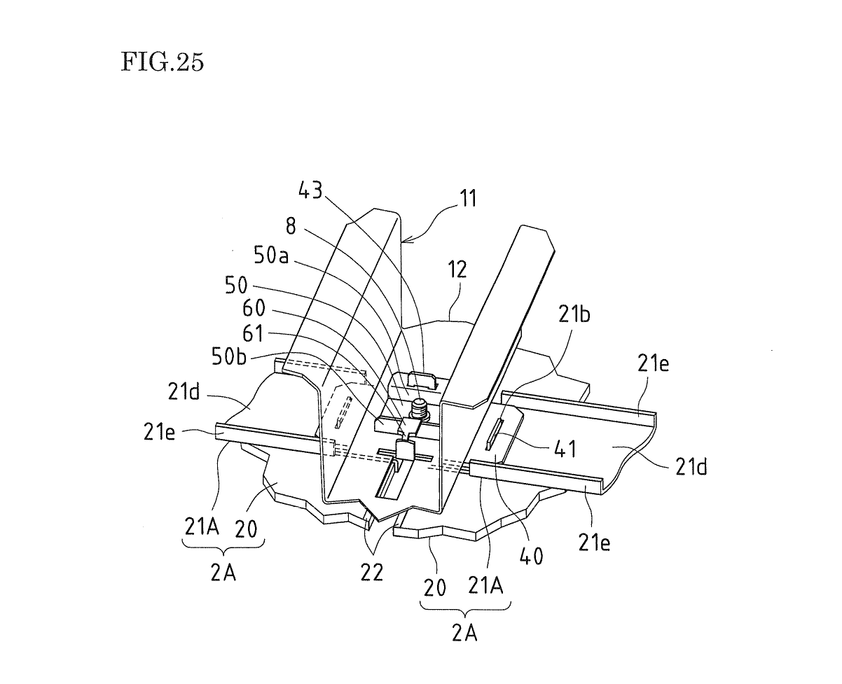

### BRIEF DESCRIPTION OF THE DRAWINGS

[FIG. 1] FIG. 1 is a perspective view of a solar cell module according to a first embodiment of the present invention.

[FIG. 2] FIG. 2 is a partially enlarged cross-sectional view of the solar cell module shown in FIG. 1.

[FIG 3] FIG. 3 is a partially enlarged and exploded perspective view of the solar cell module shown in FIG. 1.

[FIG 4] FIG. 4 is a perspective view of a solar cell attachment stand according to an embodiment of the present invention.

[FIG. 5] FIG. 5 is a partially enlarged perspective view of the solar cell attachment stand shown in FIG. 4.

[FIG 6] FIG. 6 is a side view of an attachment stand unit of the solar cell attachment stand shown in FIG. 4.

[FIG. 7] FIG. 7 is an exploded perspective view of a center attachment stand unit of attachment stand units of the solar cell attachment stand shown in FIG. 4, as viewed from an upward direction, wherein side portions of solar cell modules are attached to the center attachment stand unit.

[FIG. 8] FIG. 8 is an exploded cross-sectional view showing the state of FIG. 7.

[FIG 9] FIG. 9 is a cross-sectional view showing the state of FIG. 7.

[FIG 10] FIG. 10 is a perspective view showing the state of FIG. 7, as viewed from a downward direction.

[FIG 11] FIG. 11 is a perspective view of a part of a crosspiece of the attachment stand unit shown in FIG. 6.

[FIG 12] FIG. 12 is a perspective view of a securing fitting of the attachment stand unit shown in FIG. 6.

[FIG 13] FIG. 13 is a perspective view of a placing fitting of the attachment stand unit shown in FIG. 6.

[FIG 14] FIG. 14 is a plan view of the placing fitting shown in FIG. 13 in bent state.

[FIG 15] FIG. 15 is a perspective view of the placing fitting shown in FIG. 13 in bent state, as viewed from a front side.

[FIG 16] FIG. 16 is a perspective view of the placing fitting shown in FIG. 13 in bent state, as viewed from a back side.

[FIG. 17] FIG. 17 is a perspective view of the crosspiece with the securing fitting and the placing fitting attached.

[FIG 18] FIG. 18 is a perspective view of the crosspiece illustrating a procedure for attaching the placing fitting to the crosspiece.

[FIG. 19] FIG. 19 is a perspective view of the crosspiece illustrating a continuation of the procedure shown in FIG. 18.

[FIG. 20] FIG. 20 is a perspective view of the crosspiece illustrating a continuation of the procedure shown in FIG. 19.

[FIG 21] FIG. 21 is a perspective view of the crosspiece illustrating a continuation of the procedure shown in FIG. 20.

[FIG 22] FIG. 22 is a perspective view of a solar cell module according to a second embodiment of the present invention. [FIG 23] FIG. 23 is a partially enlarged cross-sectional view of the solar cell module shown in FIG. 22.

[FIG 24] FIG. 24 is a partially enlarged and exploded perspective view of the solar cell module shown in FIG. 22.

[FIG. 25] FIG. 25 is a perspective view of a center attachment stand unit of attachment stand units of the solar cell attachment stand shown in FIG. 4, as viewed from a downward direction, wherein side portions of the solar cell modules shown in FIG. 22 are attached to the center attachment stand unit.

### MODES FOR CARRYING OUT THE INVENTION

Embodiments of the present invention will be described below in detail by referring to the accompanying drawings.

FIG. 1 is a perspective view of a solar cell module according to a first embodiment of the present invention. FIG. 2 is a partially enlarged cross-sectional view of the solar cell module according to an embodiment of the present invention. FIG. 3 is a partially enlarged and exploded perspective view of the solar cell module according to an embodiment of the present invention.

As clearly seen from FIGS. 1 to 3, a solar cell module 2 includes a solar cell panel 20 and two reinforcing bars 21. The two reinforcing bars 21 are disposed to laterally cross the solar cell panel 20 and superimposed and adhered on the rear surface of the solar cell panel 20.

The solar cell panel 20 includes a transparent substrate such as of glass on which a thin-film semiconductor layer that carries out photoelectric conversion, an electrode film that transmits electric power, and the like are layered. The thin-film semiconductor layer, the electrode film, and the like are covered with a rear surface protective layer (also referred to as a back film or a back skin) and the like.

To each of opposing two sides 20a of the solar cell panel 20, an elastic tape 22 is adhered for shock absorption. The elastic tape 22 covers: the end surfaces of the opposing two sides 20a of the solar cell panel 20; and a peripheral edge portion of the front surface and a peripheral edge portion of the rear surface of the solar cell panel 20, the peripheral edge portions being along the two sides 20a.

Each of the reinforcing bar 21 is a rectangular and flat plate having approximately the same length as the lateral width of the solar cell panel 20. Both end portions of each reinforcing bar 21 are bent upwardly to form a hooking portion 21 a of each reinforcing bar 21. U-shaped notches are formed adjacent to both ends of the reinforcing bar 21, and the U-shaped parts are bent downwardly to form protruding engagement portions 21b. An example of the reinforcing bar 21 is made of a steel plate that is cut, bent, and subjected to plating.

An adhesive is applied to an upper surface 21c of the reinforcing bar 21, which is on the side where the hooking portions 21a protrude. The upper surface 21c of the reinforcing bar 21 is superimposed and pressed on the rear surface of the solar cell panel 20. The opposing two sides 20a of the solar cell panel 20 are held between the hooking portions 21a of the reinforcing bar 21, so that the reinforcing bar 21 is secured on the rear surface of the solar cell panel 20. Consequently, the elastic tape 22 is compressed on the rear surface of the solar cell panel 20, and the rear surface of the solar cell panel 20 is uniformly adhered to the upper surface 21c of the reinforcing bar 21 via an adhesive layer.

The height of each hooking portion 21a of the reinforcing bar 21 is lower than the thickness of the solar cell panel 20. This is for the purpose of holding the solar cell panel 20 directly with a securing fitting 3, as described later.

In this respect, the solar cell panel 20 is mainly made of a substrate such as of glass, which makes the solar cell panel 20 brittle and low in strength. Additionally, when a thin-film semiconductor layer is formed on the substrate by chemical vapor reaction (CVD), the substrate is exposed to a high temperature, which further degrades the strength of the substrate. Even with the use of, for example, tempered glass as the substrate, the tempered glass is degraded in strength after exposure to a high temperature. Thus, the tempered glass fails to maintain its original strength.

In view of this, it is conventional practice to protect the four sides of the solar cell panel by a frame member. However, the rectangular frame member is complicated in shape and has a large piece-part count, which makes difficult the attachment work with respect to the four sides of the solar cell panel. This has been a cause of difficulty in a reduction in cost of the solar cell panel. It is also common practice to put two pieces of glass together in order to improve the strength of the solar cell panel. This, however, greatly increases the weight of the solar cell panel, which has increased the cost of the solar cell panel.

In contrast, in the solar cell module 2 according to this embodiment of the present invention, two reinforcing bars 21 are adhered and secured on the rear surface of the solar cell panel 20, thereby improving the strength. The reinforcing bars 21 are simple in shape or structure and easily attachable. Further, a single piece of glass can be used to constitute the substrate, which eliminates the heaviness of the solar cell module 2 and facilitates the attempt to reduce the weight and cost of the solar cell module 2.

Each of the reinforcing bars 21 is made of a steel plate or the like and therefore has high flexural rigidity. This sufficiently increases the flexural rigidity of the solar cell module 2 compared with the solar cell panel 20 as a single entity. For example, when wind pressure acts on the solar cell panel 20, the single solar cell panel 20 as a single entity might not sufficiently strong against the wind pressure, whereas with the two reinforcing bars 21 adhered and secured on the rear surface of the solar cell panel 20, the solar cell panel 20 is reinforced to a degree enough to withstand the wind pressure.

Additionally, parts of the opposing two sides 20a of the solar cell panel 20 are protected by the hooking portions 21a of each reinforcing bar 21. The hooking portions 21a protrude beyond the opposing two sides 20a of the solar cell panel 20. Hence, when the solar cell module 2 is placed on the ground or placed upright on a platform, the hooking portions 21a directly contact the ground or the platform, which makes the opposing two sides 20a of the solar cell panel 20 detached and slightly afloat off the ground or the platform. This prevents chipping and damage to the sides 20a of the solar cell panel 20.

Additionally, the elastic tape 22 is interposed between each of the opposing two sides 20a of the solar cell panel 20 and each of the hooking portions 21a of the reinforcing bar 21. Even if the hooking portions 21a of the reinforcing bar 21 bump into the ground or the platform, the elastic tape 22 alleviates an associated shock. This also prevents chipping and damage to the sides 20a of the solar cell panel 20.

Further, as described later, when the solar cell panel 20 is installed on an attachment stand, the reinforcing bar 21 parts of the solar cell module 2 are fastened. This ensures that not all the fastening force acts on the solar cell panel 20 itself, which in turn ensures firm support of the solar cell module 2 without chipping and damage to the solar cell panel 20.

Thus, as in the solar cell module 2 according to this embodiment of the present invention, adhering and securing the two reinforcing bars 21 to the rear surface of the solar cell panel 20 sufficiently protects the solar cell panel 20 and sufficiently increases the strength of the solar cell module 2.

FIG. 4 is a perspective view of a solar cell attachment stand according to an embodiment of the present invention. FIG. 5 is a partially enlarged perspective view of the solar cell attachment stand according to an embodiment of the present invention. FIG. 6 is a side view of an attachment stand unit of the solar cell attachment stand according to an embodiment of the present invention.

The solar cell attachment stand 1 is for the purpose of supporting the solar cell module 2 of FIGS. 1 to 3. The solar cell attachment stand 1 uses three attachment stand units 10, one of which is shown in FIG. 6. The attachment stand units 10 are arranged next to each other on a roof, the ground, or the like. As shown in FIG. 4, four solar cell modules 2 are mounted and secured on the attachment stand units 10.

As shown in FIG. 6, each attachment stand unit 10 includes a crosspiece 11 and a support 16, and has a generally triangular shape in side view. Specifically, each attachment stand unit 10 is built with the slanted crosspiece 11 and the support 16 that is slanted conversely relative to the crosspiece 11 and that has a top end secured to the crosspiece 11 approximately at a position of one-fourth of the length of the crosspiece 11 from the top end thereof.

More specifically, a front bracket 17 and a rear bracket 18 are installed and secured, with a predetermined distance therebetween, on a horizontal base surface such as the ground and a flat roof. A top end portion 11a of the crosspiece 11 is coupled and secured on the front bracket 17, while the support 16 is secured to the rear bracket 18 and to the crosspiece 11 at a position of one-fourth of the length of the crosspiece 11 from the top end thereof.

Through the crosspiece 11, only the top end portion 11a has a U-shaped cross-section, while the range from the vicinity of the top end portion 11a to the rear end has a top hat-shaped cross-section (see FIG. 8). Through the support 16, only the upper end portion has a U-shaped cross-section, while the range from the vicinity of the upper end portion to the lower end of the support 16 has a top hat-shaped cross-section.

The front bracket 17, the rear bracket 18, the crosspiece 11, and the support 16 are each made of a steel plate that is cut, bent, and subjected to plating.

As clearly seen from FIG. 4, three attachment stand units 10 are arranged next to each other at intervals approximately equal to the width of the solar cell module 2. Two solar cell panels 2 are disposed vertically next to each other between the crosspiece 11 of the left attachment stand unit 10 and the crosspiece 11 of the center attachment stand unit 10. Another two the solar cell panels 2 are disposed vertically next to each other between the crosspiece 11 of the right attachment stand units 10 and the crosspiece 11 of the center attachment stand units 10. A total of four solar cell panels 2 are placed and attached on top plates 12 of the crosspieces 11 of the attachment stand units 10.

Side portions of the two, upper and lower solar cell modules 2 are placed and attached on the top plate 12 of the crosspiece 11 of the left attachment stand unit 10. Similarly, side portions of the two, upper and lower solar cell modules 2 are placed and attached on the top plate 12 of the crosspiece 11 of the right attachment stand unit 10. Further, the other side portions of the two, upper and lower solar cell modules 2 both on the left side and the right side are placed and attached on the top plate 12 of the crosspiece 11 of the center attachment stand unit 10.

In order to secure each solar cell module 2 at two positions on each of the side portions, a total of four sets of securing fittings 3 and placing fittings 4 are used (as shown in FIGS. 7 to 10). Regarding the left and right solar cell modules 2 disposed on the top plate 12 of the crosspiece 11 of the center attachment stand unit 10, two sets of securing fittings 3 and placing fittings 4 are commonly used. That is, two sets of securing fittings 3 and placing fittings 4 simultaneously secure the side portions of the left and right solar cell modules 2.

Next, a schematic description will be made with respect to an attachment structure of the solar cell module 2 to the crosspiece 11 of the attachment stand unit 10 in the solar cell attachment stand 1 of this embodiment. In the following description, the longitudinal direction of the crosspiece 11 of the attachment stand unit 10 is assumed the front-rear direction; the direction in which the three attachment stand units 10 are arranged next to each other is assumed the left-right direction; the direction in which the upper surface of the solar cell module 2 is exposed is assumed the upward direction; and the direction in which the rear surface of the solar cell module 2 is exposed is assumed the downward direction.

FIG. 7 is an exploded perspective view of the center attachment stand unit 10, as viewed from the upward direction, wherein the side portions of the left and right solar cell modules 2 are attached to the crosspiece 11 of the center attachment stand unit 10. FIGS. 8 and 9 are respectively an exploded cross-sectional view and a cross-sectional view showing the state of FIG. 7. FIG. 10 is a perspective view of the solar cell module 2 showing the state of FIG. 7, as viewed from the downward direction. It is noted that the solar cell panels 20 and the reinforcing bar 21 are separately shown in FIGS. 7 and 10.

As shown in FIGS. 7 to 10, the left and right solar cell modules 2 are attached on the top plate 12 of the crosspiece 11 of the center attachment stand unit 10 using the securing fitting 3 abutting the light receiving surface side of the solar cell module 2, the placing fitting 4 abutting the rear surface side of the solar cell module 2, and a bolt 8 serving as a fastening member.

FIG. 11 is a perspective view of a part of the crosspiece 11 of the attachment stand unit 10. As shown in FIG. 11, the top plate 12 of the crosspiece 11 has an insertion hole 13 through which the bolt 8 is inserted, a T-shaped attachment aid hole 15 for attachment of the placing fitting 4, and a positioning slit 14.

The insertion hole 13 is a thin, long hole elongated in the left-right direction for fine adjustment the insertion position of the bolt 8. The positioning slit 14 is for the purpose of inserting a positioning piece 43, described later, of the placing fitting 4. The positioning slit 14 is a thin, long hole elongated in the left-right direction for fine adjustment of the insertion position of the positioning piece 43 of the placing fitting 4.

FIG. 12 is a perspective view of the securing fitting 3. As shown in FIG. 12, the securing fitting 3 includes: protrusion pieces 32 that protrude downwardly at both front and rear end portions of a flat-plate shaped pressing plate 31; and an insertion hole 33 that penetrates through a center portion of the pressing plate 31.

The pressing plate 31 is used to press, from above, the two solar cell modules 2 adjoiningly disposed on the top plate 12 of the crosspiece 11 of the attachment stand unit 10. The insertion hole 33 is a hole through which the bolt 8 is inserted. The protrusion pieces 32 of the securing fitting 3 are inserted into the gap between the left and right solar cell modules 2.

FIG. 13 is a perspective view of the placing fitting 4. As shown in FIG. 13, the placing fitting 4 includes an upper plate 40, a lower plate 50, and a joint portion 60 that combines the upper plate 40 with the lower plate 50. A waist portion 61 to facilitate bending is disposed along the joint portion 60.

The lower plate 50 includes: a lower plate rear wall 50b that is bent at a rear end edge of the lower plate 50; and a lower plate front wall 50a that is bent at a front end edge of the lower plate 50. The lower plate 50 also includes an engagement piece 50c that is bent at an end edge of the lower plate front wall 50a.

The upper plate 40 includes engagement slits 41 formed adjacent to both left and right ends of the upper plate 40. The upper plate 40 also includes, at its rear end edge, the positioning piece 43 that is downwardly bent. The positioning piece 43 includes an engagement groove 43a.

Also, an insertion hole 42 penetrates through a center portion of the upper plate 40, and a fastening hole 51 is formed in the lower plate 50. The insertion hole 42 of the upper plate 40 is a hole through which the bolt 8 is inserted, and the fastening hole 51 of the lower plate 50 is a screw hole into which the bolt 8 as a fastening member is screwed.

As shown in FIGS. 14 to 16, the placing fitting 4 is bent at the waist portion 61 of the joint portion 60. Then, the upper plate 40 and the lower plate 50 are disposed in a mutually opposing manner with a gap therebetween. The positioning piece 43 of the upper plate 40 is fitted into a long hole 50d of the engagement piece 50c of the lower plate 50. A protruding portion 50e of the engagement piece 50c is fitted into a long hole 43a of the positioning piece 43. Thus, the upper plate 40 and the lower plate 50 are engaged with one another.

As shown in FIG. 17, with the waist portion 61 of the joint portion 60 bent, the placing fitting 4 is engaged with the T-shaped attachment aid hole 15 and the positioning slit 14 of the upper plate 12 of the crosspiece 11.

FIGS. 18 to 21 illustrate a procedure for attaching the placing fitting 4 to the upper plate 12 of the crosspiece 11 of the attachment stand unit 10.

First, as shown in FIG. 18, with both left-right ends of the upper plate 40 of the placing fitting 4 crossing the longitudinal direction of the top plate 12 of the crosspiece 11 at right angles, the lower plate 50 is put into the attachment aid hole 15 of the top plate 12 so as to insert the joint portion 60 of the placing fitting 4 through the attachment aid hole 15, as shown in FIG. 19.

Then as shown in FIG. 20, the entire placing fitting 4 is rotated at a right angle about the joint portion 60. The positioning piece 43 of the placing fitting 4 is inserted into the position slit 14 of the top plate 12 of the crosspiece 11, and the position of the placing fitting 4 in the front-rear direction is determined.

Then as shown in FIG. 21, the waist portion 61 of the joint portion 60 of the placing fitting 4 is bent by 90 degrees to dispose the lower plate 50 and the upper plate 40 in a mutually opposing manner across the top plate 12, so that the top plate 12 is held between the lower plate 50 and the upper plate 40. Thus, the top plate 12 is attached to the placing fitting 4. In this respect, the positioning piece 43 of the upper plate 40 is inserted into the long hole 50d of the engagement piece 50c of the lower plate 50, while the protruding portion 50e of the engagement piece 50c is inserted into the long hole 43a of the positioning piece 43. Thus, the lower plate 50 and the upper plate 40 are engaged with one another.

As shown in FIGS. 7 to 10, with the placing fitting 4 attached to the top plate 12 of the crosspiece 11 of the center attachment stand unit 10, an end portion of the reinforcing bar 21 of the left solar cell module 2 is placed on the upper plate 40 of the placing fitting 4 from the vicinity of the center of the upper plate 40 over the left space thereof A protruding engagement portion 21b of the reinforcing bar 21 is fitted with the left engagement slit 41 of the upper plate 40 of the placing fitting 4. Simultaneously, an end portion of the reinforcing bar 21 of the right solar cell module 2 is mounted on the upper plate 40 of the placing fitting 4 from the vicinity of the center of the upper plate 40 over the right space thereof A protruding engagement portion 21b of the placing fitting 4 is fitted with the right engagement slit 41 of the upper plate 40 of the placing fitting 4. In this manner, the left and right solar cell modules 2 are positioned with a uniform gap therebetween on the upper plate 40 of the placing plate 4.

Thus, the left and right solar cell modules 2 are positioned in a mutually opposing manner with a uniform gap therebetween on the two placing fittings 4. This ensures that on the center attachment stand unit 10, two points of the gap between the left and right solar cell modules 2 are uniform, thereby disposing the left and right solar cell modules 2 in parallel to one another.

Meanwhile, over the left and right attachment stand units 10, the reinforcing bar 21 of the left or right solar cell module 2 is mounted on the upper plate 40 of the placing fitting 4. The protruding engagement portion 21b of the reinforcing bar 21 is fitted with the engagement slit 41 of the upper plate 40 of the placing fitting 4. Thus, the left or right solar cell module 2 is positioned.

The positioning of the solar cell module 2 is carried out with the placing fitting 4 not secured. As shown in FIG. 11, the T-shaped attachment aid hole 15, the positioning slit 14, and the insertion hole 13 of the top plate 12 of the crosspiece 11 are all rectangular shaped to permit left and right movement of the placing fitting 4. Hence, not securing the placing fitting 4 ensures that the protruding engagement portions 21b of the placing fittings 4 of the left and right solar cell modules 2 are fitted with the left and right engagement slits 41 of the upper plates 40 of the placing fittings 4 while at the same time adjusting the position of the placing fittings 4 relative to the left and right solar cell modules 2.

Additionally, the placing fittings 4 are interposed between the solar cell modules 2 and the crosspiece 11. This provides tolerance for the positions of the solar cell modules 2 in the left and right direction relative to the attachment stand units 10. This ensures that even if there is a difference in intervals between the attachment stand units 10, adjusting the positions of the placing fittings 4 relative to the left and right solar cell modules 2 positions the left and right solar cell modules 2 and uniformizes the gap between the left and right solar cell modules 2. This greatly facilitates the installation work of the solar cell modules 2.

After the solar cell modules 2 are positioned, as shown in FIGS. 7 to 10, the securing fitting 3 is placed on the center attachment stand unit 10 at the reinforcing bar 21 part of each solar cell module 2. The protrusion pieces 32 of the securing fitting 3 are inserted into the gap between the left and right solar cell modules 2. Each of the protrusion pieces 32 of the securing fitting 3 is held between the hooking portions 21a of the left and right reinforcing bars 21. The bolt 8 is inserted through the insertion hole 33 of the securing fitting 3 and the insertion hole 42 of the upper plate 40. The bolt 8 is screwed into the fastening hole 51 of the lower plate 50 through the insertion hole 13 of the top plate 12 of the crosspiece 11, where the bolt 8 is tightly fastened. Thus, the solar cell panels 20 and the reinforcing bars 21 of the left and right solar cell panels 2 are held and supportably secured between the placing fitting 4 and the securing fitting 3.

Meanwhile, on the left and right attachment stand units 10, the securing fitting 3 is mounted at the reinforcing bar 21 part of the left or right solar cell module 2. The protrusion pieces 32 of the securing fitting 3 are pressed against the hooking portion 21a of the reinforcing bar 21 of the left or right solar cell module 2. The bolt 8 is inserted into the insertion hole 33 of the securing fitting 3 and the insertion hole 42 of the upper plate 40. The bolt 8 is screwed into the fastening hole 51 of the lower plate 50 through the insertion hole 13 of the top plate 12, where the bolt 8 tightly fastened. The solar cell panels 20 and the reinforcing bars 21 of the left or right solar cell module 2 are held and supportably secured between the placing fitting 4 and the securing fitting 3.

Thus, in the solar cell attachment stand 1, each solar cell panel 20 of the solar cell module 2 is fastened and supported at the reinforcing bar 21 part. This ensures that not all the fastening force acts on the solar cell panel 20 itself, which in turn ensures firm support of the solar cell module 2 without chipping and damage to the solar cell panel 20.

Additionally, the solar cell panel 20 is not directly coupled with the placing fitting 4 of the attachment stand unit 10; instead, the protruding engagement portion 21b of the reinforcing bar 21 is fitted with the engagement slit 41 of the placing fitting 4. This makes an external force difficult to directly act on the solar cell panel 20, thereby preventing chipping and damage to the solar cell panel 10.

Further, not only the solar cell module 2 but also the solar cell attachment stand 1 itself is simple in structure. This reduces the piece-part count and facilitates the installation work. In particular, when a large-scale photovoltaic power generating system is established, the facilitated installation work is a great advantage.

Next, a solar cell module according to a second embodiment of the present invention will be described. FIG. 22 is a perspective view of a solar cell module according to this embodiment. FIG. 23 is a partially enlarged cross-sectional view of the solar cell module according to this embodiment. FIG. 24 is a partially enlarged and exploded perspective view of the solar cell module according to this embodiment.

As clearly seen from FIGS. 22 to 24, a solar cell module 2A includes a solar cell panel 20 and two reinforcing bars 21A. The two reinforcing bars 21A are disposed to laterally cross the solar cell panel 20 and superimposed and adhered on the rear surface of the solar cell panel 20.

The solar cell panel 20 includes a transparent substrate such as of glass on which a thin-film semiconductor layer, an electrode film, and the like are layered. The thin-film semiconductor layer, the electrode film, and the like are covered with a rear surface protective layer and the like. To each of opposing two sides 20a of the solar cell panel 20, an elastic tape 22 is adhered for shock absorption.

The reinforcing bar 21A includes: a rectangular main plate 21d having approximately the same length as the lateral width of the solar cell panel 20; side plates 21e that are bent downwardly (to the rear surface side of the reinforcing bar 21A) on both sides of the main plate 21d; hooking portions 21a that are bent upwardly on both ends of the main plate 21d; and protruding engagement portions 21b formed by downwardly bending U-shaped notch parts formed adjacent to both ends of the main plate 21d. The height of each hooking portion 21a is lower than the thickness of the solar cell panel 20. The side plates 21e are cut off adjacent to both ends of the main plate 21d. An example of the reinforcing bar 21A is made of a steel plate that is cut, bent, and subjected to plating.

An adhesive is applied to the upper surface 21c of the main plate 21d of the reinforcing bar 21A. The upper surface 21c is superimposed and pressed on the rear surface of the solar cell panel 20. The opposing two sides 20a of the solar cell panel 20 are held between the hooking portions 21a, so that the reinforcing bar 21A is adhered and secured on the rear surface of the solar cell panel 20.

Compared with the reinforcing bar 21 of the solar cell module 2 of FIGS. 1 to 3, the reinforcing bar 21A of the solar cell module 2A is different from the reinforcing bar 21 in that the reinforcing bar 21A has the side plates 21e while being similar to the reinforcing bar 21 in that the reinforcing bar 21 A has the hooking portions 21a and the protruding engagement portions 21b. This ensures attachment of the solar cell module 2A on the top plate 12 of the crosspiece 11 of the attachment stand unit 10, similarly to the solar cell module 2 of FIG. 10. Specifically, as shown in FIG. 25, the solar cell module 2A is attached on the top plate 12 of the crosspiece 11 using a securing fitting 3 abutting the light receiving surface side of the solar cell module 2A, a placing fitting 4 abutting the rear surface side of the solar cell module 2A, and a bolt 8 serving as a fastening member. The side plates 21e are cut off adjacent to both ends of the main plate 21d. The gap between the side plates 21e is larger than the width of the upper plate 40 of the placing fitting 4. This ensures that the side plates 21e do not interfere with the crosspiece 11 and the placing fitting 4.

This ensures establishment of a photovoltaic power generating system including a plurality of solar cell modules 2 mounted on the solar cell attachment stand 1, similarly to the solar cell module 2 of FIGS. 1 to 3.

The reinforcing bar 21A has a U-shaped cross-section defined by the main plate 21d and the side plates 21e. This ensures high bending strength of the reinforcing bar 21A, which increases the strength of the solar cell module 2A to which the reinforcing bar 21A is adhered and secured. Also in the solar cell attachment stand 1, the reinforcing bar 21A is secured across the crosspieces 11, which increases the strength of the solar cell attachment stand 1.

It is noted that the prevent invention is not limited to the above-described embodiments, but can be modified in various forms. For example, the reinforcing bar 21 or 21A may not be adhered and secured to the rear surface of the solar cell panel 20 in advance; instead, the adhesion of the reinforcing bar 21 or 21A may be at the time of installation of the solar cell panel 20. Alternatively, instead of being adhered, the reinforcing bar 21 or 21A may be merely supportably secured by holding the solar cell panel 20 and the reinforcing bar 21 or 21A between the securing fitting 3 and the placing fitting 4.

It is also possible to increase the number of the reinforcing bars 21 and 21A, or superimpose the reinforcing bars 21 and 21 on each other in a crosswise manner on the rear surface of the solar cell panel 20.

It is also possible to use engagement portions of other structures or shapes to replace the protruding engagement portion 21b of the reinforcing bars 21 and 21A and the engagement slit 41 of the upper plate 40 of the placing fitting 4.

The solar cell panel is not limited to the above-described example, wherein a thin-film semiconductor layer, an electrode film, and the like are layered on a transparent substrate such as of glass, with a rear surface protective layer and the like covering and protecting the thin-film semiconductor layer, the electrode film, and the like. It is also possible to employ solar cell panels of other types, such as one using a substrate of single crystal silicon or polycrystalline silicon.

### DESCRIPTION OF THE REFERENCE NUMERAL

1 Solar cell attachment stand
2, 2A Solar cell module
3 Securing fitting
4 Placing fitting
8 Bolt
10 Attachment stand unit
11 Crosspiece
12 Top plate
16 Support
17 Front bracket
18 Rear bracket
20 Solar cell panel
21, 21A Reinforcing bar

1. A solar cell module comprising:
a solar cell panel; and
a reinforcing member adhered to a rear surface of the solar cell panel and secured across opposing two sides of the solar cell panel,
wherein the reinforcing member comprises an engagement portion protruding from a rear surface side of the reinforcing member.

2. The solar cell module according to claim 1, wherein the reinforcing member further comprises hooking portions bent at both ends of the reinforcing member, the reinforcing member being secured on the rear surface of the solar cell panel with the opposing two sides of the solar cell panel held between the hooking portions at both ends of the reinforcing member.

3. The solar cell module according to claim 2, wherein the hooking portions at both ends of the reinforcing member each have a height that is lower than a thickness of the solar cell panel.

4. The solar cell module according to claim 1, further comprising a shock absorbing member interposed between portions at both ends of the reinforcing member and the opposing two sides of the solar cell panel.

5. The solar cell module according to claim 1, wherein the solar cell panel comprises a thin-film semiconductor layer on a substrate, the thin-film semiconductor being configured to carry out photoelectric conversion.

6. The solar cell module according to claim 1, wherein the reinforcing member comprises side portions bent at the both sides of the reinforcing member.

7. A solar cell attachment stand to support a solar cell panel, the solar cell attachment stand comprising:
a reinforcing member superimposed on a rear surface of the solar cell panel and secured across opposing two sides of the solar cell panel;
at least one placing member on which the reinforcing member on the rear surface of the solar cell panel is placed and secured; and
fastening means for fastening the placing member to the reinforcing member on the rear surface of the solar cell panel,
wherein the placing member and the reinforcing member on the rear surface of the solar cell panel comprise engagement portions engaged with one another.

8. The solar cell attachment stand according to claim 7, wherein the reinforcing member further comprises hooking portions bent at both ends of the reinforcing member, the reinforcing member being secured on the rear surface of the solar cell panel with the opposing two sides of the solar cell panel held between the hooking portions at both ends of the reinforcing member.

9. The solar cell attachment stand according to claim 8, wherein the hooking portions at both ends of the reinforcing member each have a height that is lower than a thickness of the solar cell panel.

10. The solar cell attachment stand according to claim 7, wherein a solar cell module comprising the reinforcing member integrally adhered to the rear surface of the solar cell panel is used.

11. The solar cell attachment stand according to claim 10, further comprising a shock absorbing member interposed between portions at both ends of the reinforcing member and the opposing two sides of the solar cell panel.

12. The solar cell attachment stand according to claim 7, further comprising a plurality of crosspieces disposed in parallel to each other with a distance provided therebetween, the distance being at least same as a separation distance between the opposing two sides of the solar cell panel,
wherein the at least one placing member comprises a plurality of placing members movably supported on the respective crosspieces in a solar cell panel aligning direction,
wherein a plurality of solar cell panels are disposed between the crosspieces,
wherein the placing members are movable to adjust positions of the placing members to positions of reinforcing members of adjacent solar cell panels among the plurality of solar cell panels, and
wherein the engagement portion of each of the placing members and the engagement portion of each of the reinforcing members on the rear surface of the solar cell panel are engaged with one another by fastening of the fastening means.

13. The solar cell attachment stand according to claim 7, wherein the reinforcing member comprises side portions bent at the both sides of the reinforcing member.

14. A photovoltaic power generating system comprising the solar cell attachment stand according to claim 7.
